(19) United States
(12) Patent Application Publication
(10) Pub. No.: US 2024/0311519 A1
(43) Pub. Date: Sep. 19, 2024

(54) USING COMPUTER MODELS TO DESIGN OBJECTS WITH SELF-HEALING MATERIAL ZONES

(71) Applicant: INTERNATIONAL BUSINESS MACHINES CORPORATION, ARMONK, NY (US)

(72) Inventors: Jeremy R. Fox, Georgetown, TX (US); Jill S. Dhillon, Jupiter, FL (US); Tushar Agrawal, West Fargo, ND (US); Sarbajit K. Rakshit, Kolkata (IN)

(21) Appl. No.: 18/185,534

(22) Filed: Mar. 17, 2023

(51) Int. Cl. G06F 30/10; G06F 30/27

(52) U.S. Cl. CPC G06F 30/10; G06F 30/27

(57) ABSTRACT

A computer implemented method that includes modeling an existing physical object as a computer based model including data representing physical dimensions of the physical object and material properties reflecting the materials of which the physical object is made, receiving a physical object usage data set including information about physical operations and/or ambient conditions, running a computer simulation on the computer based model of the physical object where the simulation includes computer simulation of the physical operations and/or ambient conditions included in the physical object usage data set, determining an area where a material defect zone on or in the physical object where a material defect is likely to occur in the physical object based on the running of the computer simulation, and applying self-healing material to the material defect zone of the physical object.

### BACKGROUND

The present invention relates generally to the fields of: computer models object designs and computer simulations involving the same, three dimensional (3D) printing and self-healing materials.

The Wikipedia entry for “self healing material” (as of 23 Feb. 2023) states, in part, as follows: “Self-healing materials are artificial or synthetically created substances that have the built-in ability to automatically repair damages to themselves without any external diagnosis of the problem or human intervention. Generally, materials will degrade over time due to fatigue, environmental conditions, or damage incurred during operation. Cracks and other types of damage on a microscopic level have been shown to change thermal, electrical, and acoustical properties of materials, and the propagation of cracks can lead to eventual failure of the material. In general, cracks are hard to detect at an early stage, and manual intervention is required for periodic inspections and repairs. In contrast, self-healing materials counter degradation through the initiation of a repair mechanism that responds to the micro-damage. Some self-healing materials are classed as smart structures, and can adapt to various environmental conditions according to their sensing and actuation properties. Although the most common types of self-healing materials are polymers or elastomers, self-healing covers all classes of materials, including metals, ceramics, and cementitious materials. Healing mechanisms vary from an intrinsic repair of the material to the addition of a repair agent contained in a microscopic vessel. For a material to be strictly defined as autonomously self-healing, it is necessary that the healing process occurs without human intervention. Self-healing polymers may, however, activate in response to an external stimulus (light, temperature change, etc.) to initiate the healing processes. A material that can intrinsically correct damage caused by normal usage could prevent costs incurred by material failure and lower costs of a number of different industrial processes through longer part lifetime, and reduction of inefficiency caused by degradation over time.” (footnotes omitted)

The Wikipedia entry for “computer simulation” (as of 23 Feb. 2023) states, in part, as follows: “Computer simulation is the process of mathematical modelling, performed on a computer, which is designed to predict the behaviour of, or the outcome of, a real-world or physical system. The reliability of some mathematical models can be determined by comparing their results to the real-world outcomes they aim to predict. Computer simulations have become a useful tool for the mathematical modeling of many natural systems in . . . manufacturing, as well as human systems in . . . engineering. Simulation of a system is represented as the running of the system's model. It can be used to explore and gain new insights into new technology and to estimate the performance of systems too complex for analytical solutions. Computer simulations are realized by running computer programs that can be either small, running almost instantly on small devices, or large-scale programs that run for hours or days on network-based groups of computers. The scale of events being simulated by computer simulations has far exceeded anything possible (or perhaps even imaginable) using traditional paper-and-pencil mathematical modeling . . . . A computer model is the algorithms and equations used to capture the behavior of the system being modeled. By contrast, computer simulation is the actual running of the program that contains these equations or algorithms. Simulation, therefore, is the process of running a model. Thus one would not ‘build a simulation’; instead, one would ‘build a model (or a simulator)’, and then either ‘run the model’ or equivalently ‘run a simulation’ . . . . Computer simulations are used in a wide variety of practical contexts, such as: . . . behavior of structures (such as buildings and industrial parts) under stress and other conditions . . . modeling car crashes to test safety mechanisms in new vehicle models . . . ” (footnotes omitted)

3D printing or additive manufacturing is a process of making three dimensional solid objects from a digital file. The creation of a 3D printed object is achieved using additive processes. In an additive process an object is created by laying down successive layers of material until the object is created. Each of these layers can be seen as a thinly sliced cross-section of the object. 3D printing is the opposite of subtractive manufacturing which is cutting out/hollowing out a piece of metal or plastic with for instance a milling machine. 3D printing enables one to produce complex shapes using less material than traditional manufacturing methods. 3D printing is being used for manufacturing 3D objects, or can also be used for repairing 3D object, like structure, etc. There are various 3D printing systems are there, where the 3D printing system can use the capability of robotic system can perform self-mobility, collaborating with swarm 3D printing robots and can perform printing in a collaborative manner.

### SUMMARY

According to an aspect of the present invention, there is a method, computer program product and/or system that performs the following operations (not necessarily in the following order): (i) modeling an existing physical object as a computer based model including data representing physical dimensions of the physical object and material properties reflecting the materials of which the physical object is made; (ii) receiving a physical object usage data set including information about physical operations and/or ambient conditions in which the physical object has been used or may be used in the future; (iii) running a computer simulation on the computer based model of the physical object where the simulation includes computer simulation of the physical operations and/or ambient conditions included in the physical object usage data set; (iv) determining an area where a material defect zone on or in the physical object where a material defect is likely to occur in the physical object based on the running of the computer simulation; and (v) applying self-healing material to the material defect zone of the physical object.

### BRIEF DESCRIPTION OF THE DRAWINGS

FIG. 1A is a block diagram of a first embodiment of a system according to the present invention;

FIG. 2 is a block diagram showing a machine logic (for example, software) portion of the first embodiment system;

FIG. 3 is a flowchart showing a first embodiment method performed, at least in part, by the first embodiment system;

FIG. 4A shows a physical object maintenance environment at a first time;

FIG. 4B shows the physical object maintenance environment at a second time;

FIG. 4C shows the physical object maintenance environment at a third time; and

FIG. 5 is a flowchart showing a second embodiment method according to the present invention.

### DETAILED DESCRIPTION

This Detailed Description section is divided into the following subsections: (i) The Hardware and Software Environment; (ii) Example Embodiment; (iii) Further Comments and/or Embodiments; and (iv) Definitions.

### I. The Hardware and Software Environment

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

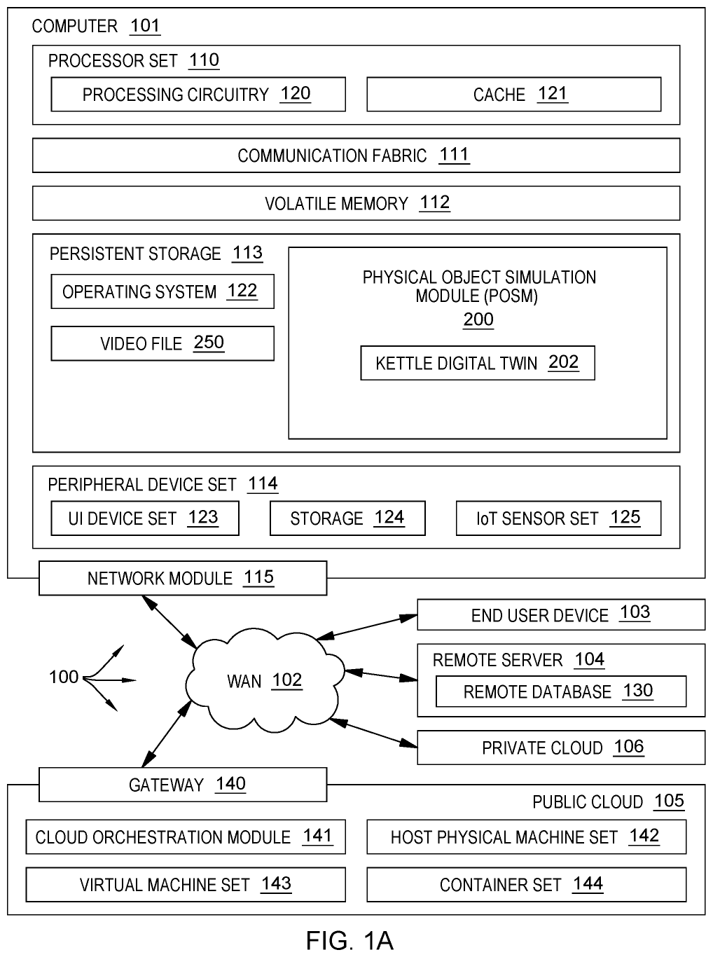

As shown in FIG. 1A, computing environment 100 contains an example of an environment for the execution of at least some of the computer code involved in performing the inventive methods, such as physical object simulation module (POSM) 200 (also herein sometimes referred to as block 200, includes kettle digital twin 202). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

### II. Example Embodiment

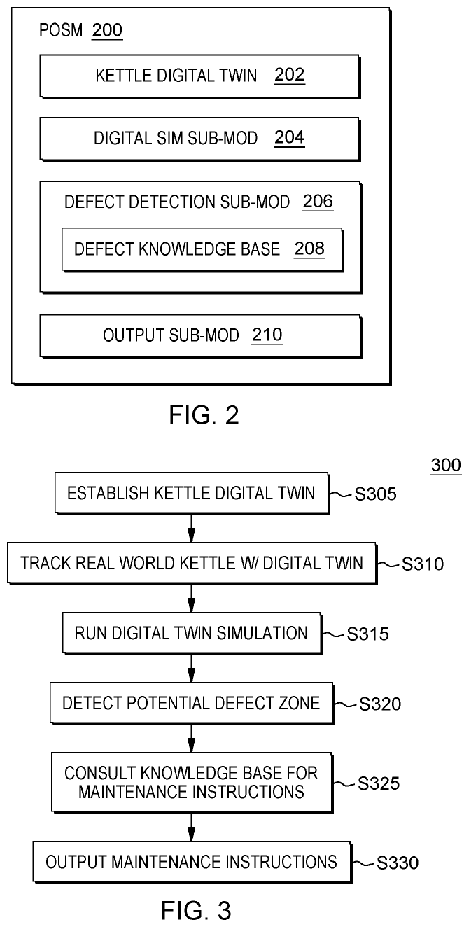

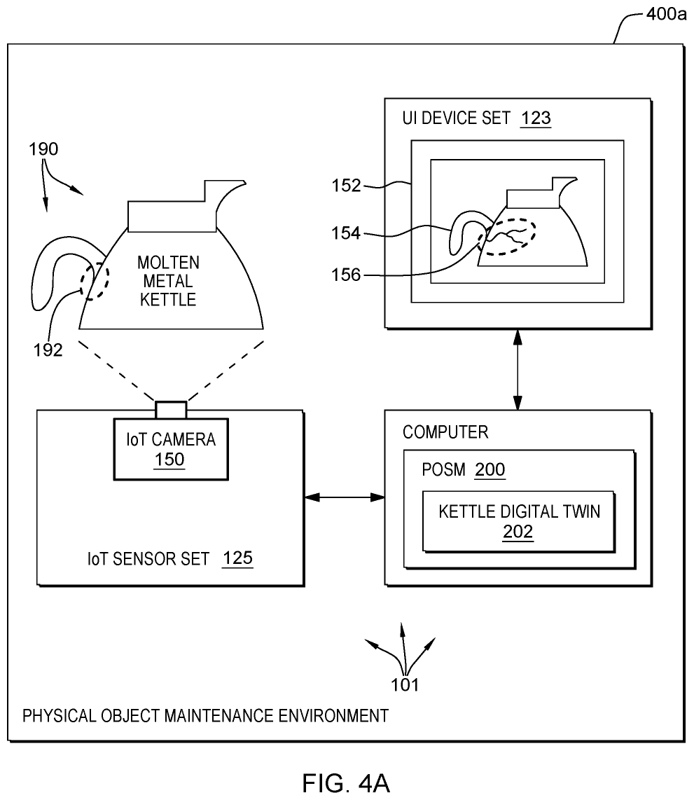

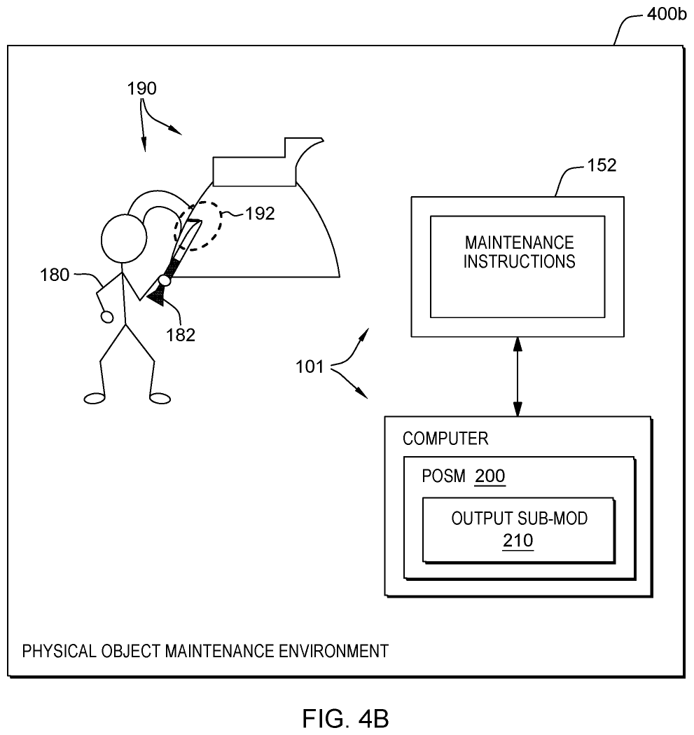

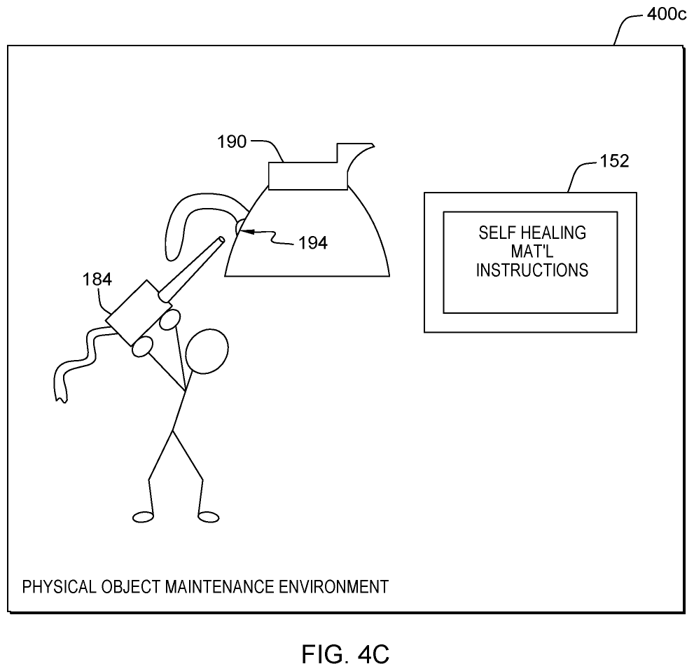

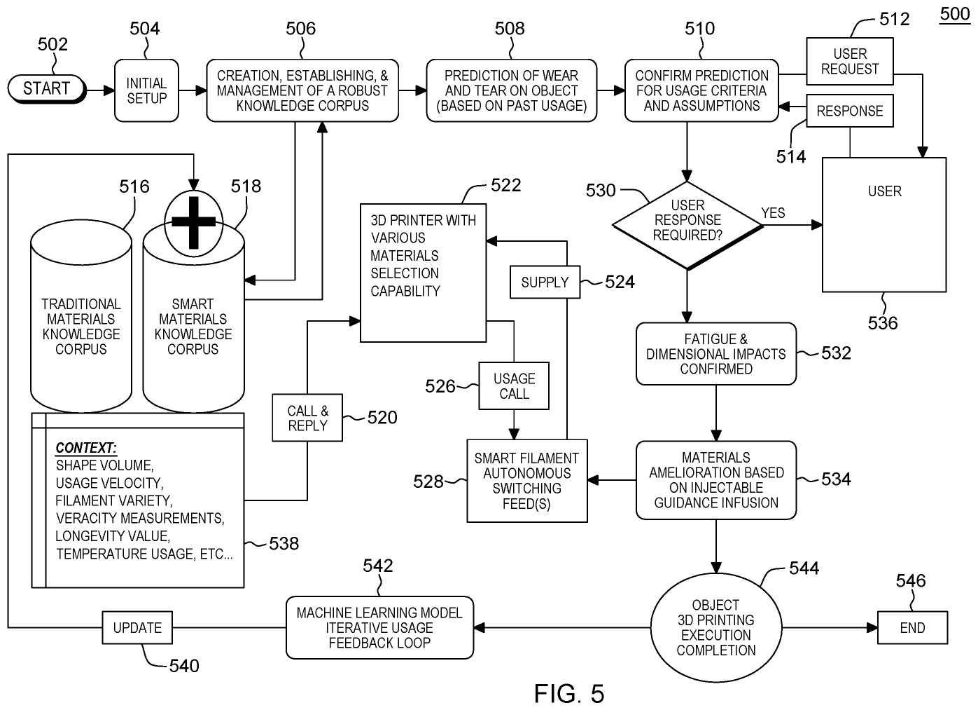

Computing environment 100 is an embodiment of a computing environment where computer simulations of physical object models are performed. FIGS. 4A to 4C show a physical object maintenance environment where a lager industrial kettle for holding molten metal is maintained so that it will be good for use in smelting processes (not shown). As shown in FIG. 3, flowchart 300 shows an example method according to the present invention. As shown in FIG. 2, POSM 200 performs or controls performance of at least some of the method operations of flowchart 300. This method and associated software will now be discussed, over the course of the following paragraphs, with extensive reference to the blocks of the first four figures.

Processing begins at operation S305 of flow chart 300, where a digital twin 202 of molten metal kettle 190 of physical object maintenance environment 400a,b,c is created. This digital twin is one species of a category herein called “computer model of a physical object.” So, at the end of operation S305 there is a physical object (in this example a large kettle) and a computer model (in this example, a digital twin) corresponding to it. It is noted that digital twin 2020 includes data representing physical dimensions of kettle 190 and material properties reflecting the materials of which kettle 190.

OPERATION S310: digital simulation sub-mod 204 receives a physical object usage data set including information about physical operations and ambient conditions in which kettle 190 has been used or may be used in the future. In this example the physical operations include instances of lifting kettle 190 by its handle and the associated data of how much molten metal is in the kettle each time it is lifted in the course of normal smelting operations. The ambient conditions would include temperatures encountered by the kettle when it is in the vicinity of hot smelting fires. As shown in FIG. 4A of physical object maintenance environment 400a, in this example, the tracking of kettle usage is performed by Internet of Things IoT sensor set 125 (including IoT camera 150).

OPEARATION S315: digital simulation sub-module 204 runs a computer simulation on kettle digital twin 202 where the simulation includes computer simulation of the physical operations and/or ambient conditions included in the physical object usage data set. In this example the parameters and operations of the simulation are informed by the usage data set received at operation S310. In this example, the physical object usage data set that effectively defines the simulation is limited to information gleaned from tracking actual usage of the actual kettle. Additionally or alternatively, the simulation may be informed by one or more of the following: actual usage of similar kettles, expert information regarding how similar kettles are typically used and/or usage of objects dissimilar to kettle 190 (for example, a pair of tongs made of a similar mater to kettle 190 and exposed to similar ambient temperatures).

OPERATION S320: defect detection sub module 206 determines an area where a material defect zone on or in kettle 190 where a material defect is likely to occur in the physical object based on the running of the computer simulation at operation S315. In this embodiment, the material defect indicated by the simulation is cracking. Alternatively, in various embodiments, the material defect could be any sort of material defects, such as melting, exploding, expansion, contraction, warping, weakening, necking and so on. Physical object maintenance environment 400a (shown in FIG. 4A) shows the material defect zone both on a computer display of digital twin 202 and with respect to the real world instantiation of kettle 190 itself. More specifically: (i) material defect zone 192 is indicated on kettle 190 (notice that no cracks have yet formed); and (ii) digital twin representation of material defect zone 156 is shown on display 154 of digital twin 202 on display device 154 of UI device set 123 of computer 101 (notice that the simulation does show the cracks).

OPERATION S325: defect knowledge base 208 of defect detection sub module 206 is consulted automatically to determine what maintenance actions should be recommended to remedy the potential material defect indicated by the simulation of the computer model of the physical object. In this example, the maintenance recommended is as follows: (i) cut a shallow notch where the underside of the kettle handle meets the vessel portion of the kettle using cutting tool 182; and (ii) apply self-healing material with a hand-held applicator device 184.

OPEARATION S330: output sub module 210 outputs the self-healing material maintenance instructions. This is shown on display 152 in FIGS. 4B and 4C. In this example, and as shown in FIGS. 4B and 4C, maintenance person 180 uses cutting tool 182 to cut the notch at material defect zone 192 of kettle 190 and then uses hand-held applicator device 184 to apply self-healing material 194 in the notch. Alternatively, and as discussed in the next sub-section of this Detailed Description section, in some embodiments a 3D printer is used to apply the self-healing material, which may reduce or eliminate the need for efforts and attention of maintenance person 180.

In various embodiments, the physical object may relate to one of the following areas of commercial enterprise: aircraft, land vehicles, water vehicles, space vehicles, mining equipment, mass production of consumer goods, agricultural equipment, computer hardware, furniture, architectural structures and/or physical infrastructure.

### III. Further Comments and/or Embodiments

PROBLEM STATEMENT: Some embodiments of the present invention recognize one, or more, of the following facts, potential problems and/or potential areas for improvement with respect to the current state of the art: (i) in various machines and structures several parts and components (herein sometimes referred to as “physical objects”) are used; (ii) these parts/components are prone to problems such as, but not limited to, cracks, micro-cracks, leaks, etc.; (iii) there is also wear and tear on these parts/components that can cause failure of the equipment or collapse of a larger structure including the part/component as a constituent part; (iv) 3D Objects like parts in a structure (e.g., a bridge) or parts in an equipment are exposed to external factors like weather, friction, usage, and the like, resulting in wear and tear; (v) if the wear and tear is not prevented on time, then the functionality provided can be broken; and/or (vi) parts/components of all 3D objects can be affected by weather, changes in temperature, ratio of heat to humidity, as it relates to their specific combination of molecular materials and hence, lifespan, reliability, and durability.

SOLUTION STATEMENT: Some embodiments of the present invention may include one, or more, of the following operations, features, characteristics and/or advantages: (i) use computer model/simulation of physical object to predict wear and tear or cracks in a 3D object based on simulation of its usage, location and weather conditions; (ii) modify the 3D model for printing (SLT (stereolithography)) to include self-healing material on those portions that are prone to wear and tear or cracks during the object's life; and projected usage; (iii) predict and recommend what modifications will be needed under changing conditions, weather, in context of the molecular structure of the materials used; (iv) analyze the shape, size and/or dimensions of the object and the amount of the identified wear and tear or cracks in a 3D object; (v) apply self-healing material to the real world physical instantiation of the physical object (for example, by using a 3D printer to apply the self-healing material) to improve the life and sustainability of the object; (vi) apply appropriate temperature, compressed air to the physical object (for example, by a 3D printer) so that the self-healing material or embedded capsules can be added or activated in the correct spot where a failure can or is occurring, and remediate with its self-healing properties; (vii) create a knowledge corpus of data related to wear and tear and predicted defects in the physical object; and/or (viii) use machine learning (ML) based on historical data for determining modifications in the 3D model to include self-healing material as a part of the printing process.

Some embodiments of the present invention may include one, or more, of the following operations, features, characteristics and/or advantages: (i) uses computer simulation to predict wear and tear or cracks in a 3D object based on simulation of its usage; (ii) receiving data related to the 3D object; (iii) simulating usage of the 3D object; (iv) predicting wear and tear or cracks in the 3D object based on the simulation; (v) modifying the 3D object to include self-healing material on those portions that are prone to wear and tear or cracks during the object's life; (vi) identifying the specific tear or crack in the actual 3D object; (vii) simulating the activation and opening of micro-capsules to bind a crack or tear and polymerizing to reinforce the affected aspect of the 3D object; (ix) capillary action draws the self healing material monomer into a crack where it is exposed to the catalyst and thus polymerizes; (x) the polymerized material binds the two faces of the crack together; and/or (xi) the material thus heals itself in response to damage.

Some embodiments of the present invention may include one, or more, of the following operations, features, characteristics and/or advantages: (i) creating a knowledge corpus of data related to wear and tear and predicted cracks; (ii) receiving data related to wear and tear or cracks in 3D objects; (iii) storing the data in a knowledge corpus; (iv) analyzing the data to identify trends; (v) proposing modifications to 3D models to include self-healing material based on the trends; (vi) proposing how and when to fill the identified wear and tear or cracks with self-healing material; (vii) breaking and opening of micro-capsules to bind a crack or tear and polymerizing to reinforce the affected aspect of the 3D object; (viii) uses weather data and machine learning to incorporate feedback from case implementations as inputs into knowledge corpus; and/or (ix) knowledge corpus refines and further builds over time corpus covering all elements and aspects learned from the implementation of the self-healing material.

An embodiment of a method according to the present invention includes nine (9) operations. The nine operations are respectively described in the following nine (9) paragraphs.

KNOWLEDGE CORPUS CREATION (first operation): Establishing a Robust Knowledge Corpus for Object Projected Usage: The system will create a knowledge corpus of data related to wear and tear and predicted cracks etc. It will learn from the historical data and propose modifications in the 3D model to include self-healing material as a part of the printing process. The following Python Code Snippet may be used:

```
import pandas as pd
from sklearn.feature_extraction.text import TfidfVectorizer
def create_knowledge_corpus(data, features):
  “““
  Establish a robust knowledge corpus for object projected usage.
  :param data: A dataframe containing the data to be used for
creating the corpus.
  :param features: A list of features to be used for creating the
corpus.
  :return: A corpus consisting of the specified features.
  ”””
  # Initialize the tf-idf vectorizer.
  tfidf_vectorizer = TfidfVectorizer( )
  # Fit the tf-idf vectorizer on the data.
  tfidf_vectorizer.fit(data[features])
  # Transform the data using the fitted vectorizer.
  corpus = tfidf_vectorizer.transform(data[features])
  # Convert a collection of raw documents to a matrix of TF-IDF
features
  return corpus
```

PREDICTION OF WEAR AND TEAR ON OBJECT (second operation): The proposed system will predict wear and tear or cracks in a 3D object based on simulation of its usage, location and weather conditions; accordingly. Utilizing a leaner regression modeling technique, the system can confirm the following predictions.

CONFIRM ASSUMPTIONS FOR 3D PRINTABLE OBJECT USAGE CRITERIA and CONDITIONS (third operation): The proposed system will predict and recommend what modifications will be needed under changing conditions, weather, in context of the molecular structure of the materials used. The following Python Code Snippet may be used in this operation:

```
import numpy as np
import pandas as pd
import matplotlib.pyplot as plt
from sklearn.linear_model import LinearRegression
from sklearn.metrics import mean_squared_error, r2_score
def predict_wear_and_tear(data, object_type, location,
weather_conditions):
  # Fit a linear regression model to the data
  model = LinearRegression( )
  model.fit(data, object_type, location, weather_conditions)
  # Make predictions using the model
  predictions = model.predict(data)
  # Calculate and return the RMSE and R2 score
  rmse = np.sqrt(mean_squared_error(object_type, predictions))
  r2 = r2_score(object_type, predictions)
  return rmse, r2
```

FATIGUE and DIMENSIONAL IMPACTS ON PRINTABLE OBJECT (fourth operation): The proposed system will analyze the shape and size (dimension) of the object and the amount of the identified wear and tear or cracks in a 3D object.

APPLICATION OF AIR AND TEMPERATURE INJECTION (fifth operation): The 3D printer will apply appropriate temperature, compressed air, etc. so that the self-healing material or embedded capsules can be added or activated in the correct spot where a failure can or is occurring and generate the recommendation actions with its self-healing properties. The following Python Code Snippet may be used in this operation:

```
def
fatigue_and_dimensional_impacts_on_printable_object(object_3d,
wear_and_tear, cracks):
  object_shape = object_3d.shape
  object_size = object_3d.size
  if wear_and_tear > 0 or cracks > 0:
    print(“There is wear and tear or cracks on the object.”)
    print(“The object's shape is: ”, object_shape)
    print(“The object's size is: ”, object_size)
    print(“The object will need to be repaired.”)
  else:
    print(“There is no wear and tear or cracks on the
object.”)
    print(“The object's shape is: ”, object_shape)
    print(“The object's size is: ”, object_size)
    print(“The object does not need to be repaired.”)
def application_of_air_and_temperature_injection(object_3d,
temperature, compressed_air):
  if temperature > 0 and compressed_air > 0:
    print(“The 3D printer will apply appropriate
temperature, compressed air, etc. so that the self-healing
material or embedded capsules can be added or activated in the
correct spot where a failure can or is occurring.”)
    print(“The object's new shape is: ”, object_3d.shape)
    print(“The object's new size is: ”, object_3d.size)
  else:
    print(“The 3D printer will not apply appropriate
temperature, compressed air, etc. so that the self-healing
material or embedded capsules can be added or activated in the
correct spot where a failure can or is occurring.”)
```

SELF-HEALING MATERIALS FILAMENT ADDITIONS (sixth operation): The proposed system will modify the 3D model for printing (SLT) to include self-healing material on those portions that are prone to wear and tear or cracks during the object's life; and projected usage.

MATERIALS AMEILIRATION BASED ON INJECTION GUIDANCE (seventh operation): The system will then instruct a 3D Printer to fill it with self-healing material to improve the life and sustainability of the object. The following Python Code Snippet may be used in this operation:

```
def self_healing_materials_filament_additions(stl_file,
self_healing_material_file):
  “““
  This function will take in a 3D model for printing (STL file)
  and add self-healing material to those portions that are
  prone to wear and tear or cracks during the object's life.
  ”””
  # Load STL file
  model = np.load(stl_file)
  # Load self-healing material file
  self_healing_material = np.load(self_healing_material_file)
  # Add self-healing material to STL file
  for i in range(model.shape[0]):
    for j in range(model.shape[1]):
      for k in range(model.shape[2]):
        if model[i,j,k] == 1:
          model[i,j,k] = self_healing_material[i,j,k]
  # Save STL file
  np.save(stl_file, model)
def materials_amelioration_based_on_injection_guidance(stl_file,
self_healing_material_file):
  “““
  This function will take in a 3D model for printing (STL file)
  and a self-healing material file. It will then instruct a 3D
  Printer to fill the STL file with self-healing material to
  improve the life and sustainability of the object.
  ”””
  # Load STL file
  model = np.load(stl_file)
  # Load self-healing material file
  self_healing_material = np.load(self_healing_material_file)
  # Inject self-healing material into STL file
  for i in range(model.shape[0]):
    for j in range(model.shape[1]):
      for k in range(model.shape[2]):
        if model[i,j,k] == 0:
          model[i,j,k] = self_healing_material[i,j,k]
  # Save STL file
  np.save(stl_file, model)
```

PRINTING THE 3D OBJECT (eighth operation): The planned object will be 3D printed via the process defined above utilizing the self-healing materials when and where required within the object printing.

USER ENABLED-ITERATIVE FEEDBACK LOOP (ninth operation): An iterative feedback loop will be available to the user to provide both positive and negative feedback to the 3D printer through updating the knowledge corpus with problems, concerns, structural strength composition, general comments, and any other feedback that would enable the system to strengthen the quality of other 3D prints in the future.

As shown in FIG. 5, flowchart 500 that includes blocks respectively representing the following operations: start block 502; initial setup block 504; creation, establishing and management of a robust knowledge corpus block 506; prediction of wear and tear on object (based on past usage) block 508; confirm prediction for usage criteria and assumptions block 510; user request block 512; response block 514; traditional materials knowledge corpus storage 516; smart materials knowledge corpus storage 518; call and reply block 520; 3D printer with various materials selection capabilities block 522; supply block 524; usage call block 526; smart filament autonomous switching feed(s) block 528; user response required decision block 530; Fatigue and dimensional impacts confirmed block 532; materials amelioration based on injectable guidance infusion block 534; user block 536; context, shape, volume, usage velocity, filament variety, veracity measurements, longevity value, temperature usage, etc. block 538; update block 540; machine learning model interactive usage feedback loop block 542; object 3D printing execution completion block 544; and end block 546.

Some embodiments of the present invention may include one, or more, of the following operations, features, characteristics and/or advantages: (i) modifies the 3D model for printing (SLT) to include self-healing material on the portions that are prone to wear and tear or cracks during the object's life; (ii) projected usage is based on simulation of its usage, location and weather conditions; (iii) predicts and recommends what modifications to the SLT file will be needed under changing conditions, weather, in context of the molecular structure of the materials used; (iv) analyzes the shape and size (dimension) of the object and the amount of the identified wear and tear or cracks in a 3D object; (v) instructs a 3D printer to be filled with self-healing material to improve the life and sustainability of the object; (vi) creates a knowledge corpus of data related to wear and tear and predicted cracks, etc.; and/or (vii) learns from the historical data and proposes modifications in the 3D model to include self-healing material as a part of the printing process.

### IV. Definitions

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein are believed to potentially be new, this understanding, as indicated by use of the term “present invention,” is tentative and provisional and subject to change over the course of patent prosecution as relevant information is developed and as the claims are potentially amended.

Embodiment: see definition of “present invention” above-similar cautions apply to the term “embodiment.”

and/or: inclusive or; for example, A, B “and/or” C means that at least one of A or B or C is true and applicable.

Including/include/includes: unless otherwise explicitly noted, means “including but not necessarily limited to.”

Module/Sub-Module: any set of hardware, firmware and/or software that operatively works to do some kind of function, without regard to whether the module is: (i) in a single local proximity; (ii) distributed over a wide area; (iii) in a single proximity within a larger piece of software code; (iv) located within a single piece of software code; (v) located in a single storage device, memory or medium; (vi) mechanically connected; (vii) electrically connected; and/or (viii) connected in data communication.

Set of thing(s): does not include the null set; “set of thing(s)” means that there exist at least one of the thing, and possibly more; for example, a set of computer(s) means at least one computer and possibly more.

What is claimed is:

1. A computer-implemented method (CIM) comprising:
modeling an existing physical object as a computer based model including data representing physical dimensions of the physical object and material properties reflecting the materials of which the physical object is made;
receiving a physical object usage data set including information about physical operations and/or ambient conditions in which the physical object has been used or may be used in the future;
running a computer simulation on the computer based model of the physical object where the simulation includes computer simulation of the physical operations and/or ambient conditions included in the physical object usage data set;
determining an area where a material defect zone on or in the physical object where a material defect is likely to occur in the physical object based on the running of the computer simulation; and
applying self-healing material to the material defect zone of the physical object.

2. The CIM of claim 1 wherein the self-healing material is applied by a 3D printer.

3. The CIM of claim 1 wherein the self-healing material is applied to exterior surfaces of the physical object.

4. The CIM of claim 1 wherein the application of self-healing material includes removal of material from the physical object so that the self-healing material will be applied to an interior zone withing the physical object.

5. The CIM of claim 1 wherein the physical object relates to one of the following areas of commercial enterprise: aircraft, land vehicles, water vehicles, space vehicles, mining equipment, mass production of consumer goods, agricultural equipment, computer hardware, furniture, architectural structures and/or physical infrastructure.

6. The CIM of claim 1 further comprising:
receiving historical data training sets respectively including information regarding performance of the computer simulation in the past against real world observations of historical physical objects; and
performing unsupervised machine learning with respect to software controlling the computer simulation based on the historical data training sets.

7. A computer program product (CPP) comprising:
a set of storage device(s); and
computer code stored collectively in the set of storage device(s), with the computer code including data and instructions to cause a processor(s) set to perform at least the following operations:
modeling an existing physical object as a computer based model including data representing physical dimensions of the physical object and material properties reflecting the materials of which the physical object is made,
receiving a physical object usage data set including information about physical operations and/or ambient conditions in which the physical object has been used or may be used in the future,
running a computer simulation on the computer based model of the physical object where the simulation includes computer simulation of the physical operations and/or ambient conditions included in the physical object usage data set,
determining an area where a material defect zone on or in the physical object where a material defect is likely to occur in the physical object based on the running of the computer simulation, and
applying self-healing material to the material defect zone of the physical object.

8. The CPP of claim 7 wherein the self-healing material is applied by a 3D printer.

9. The CPP of claim 7 wherein the self-healing material is applied to exterior surfaces of the physical object.

10. The CPP of claim 7 wherein the application of self-healing material includes removal of material from the physical object so that the self-healing material will be applied to an interior zone withing the physical object.

11. The CPP of claim 7 wherein the physical object relates to one of the following areas of commercial enterprise: aircraft, land vehicles, water vehicles, space vehicles, mining equipment, mass production of consumer goods, agricultural equipment, computer hardware, furniture, architectural structures and/or physical infrastructure.

12. The CPP of claim 7 wherein the computer code further includes instructions for causing the processor(s) set to perform the following operation(s):
receiving historical data training sets respectively including information regarding performance of the computer simulation in the past against real world observations of historical physical objects; and
performing unsupervised machine learning with respect to software controlling the computer simulation based on the historical data training sets.

13. A computer system (CS) comprising:
a processor(s) set;
a set of storage device(s); and
computer code stored collectively in the set of storage device(s), with the computer code including data and instructions to cause the processor(s) set to perform at least the following operations:
modeling an existing physical object as a computer based model including data representing physical dimensions of the physical object and material properties reflecting the materials of which the physical object is made,
receiving a physical object usage data set including information about physical operations and/or ambient conditions in which the physical object has been used or may be used in the future,
running a computer simulation on the computer based model of the physical object where the simulation includes computer simulation of the physical operations and/or ambient conditions included in the physical object usage data set,
determining an area where a material defect zone on or in the physical object where a material defect is likely to occur in the physical object based on the running of the computer simulation, and
applying self-healing material to the material defect zone of the physical object.

14. The CS of claim 13 wherein the self-healing material is applied by a 3D printer.

15. The CS of claim 13 wherein the self-healing material is applied to exterior surfaces of the physical object.

16. The CS of claim 13 wherein the application of self-healing material includes removal of material from the physical object so that the self-healing material will be applied to an interior zone withing the physical object.

17. The CS of claim 13 wherein the physical object relates to one of the following areas of commercial enterprise: aircraft, land vehicles, water vehicles, space vehicles, mining equipment, mass production of consumer goods, agricultural equipment, computer hardware, furniture, architectural structures and/or physical infrastructure.

18. The CS of claim 13 wherein the computer code further includes instructions for causing the processor(s) set to perform the following operation(s):
receiving historical data training sets respectively including information regarding performance of the computer simulation in the past against real world observations of historical physical objects; and
performing unsupervised machine learning with respect to software controlling the computer simulation based on the historical data training sets.
